(19) United States
(12) Patent Application Publication
(10) Pub. No.: US 2017/0075105 A1
(43) Pub. Date: Mar. 16, 2017

(54) RESONANCE-ACTUATION OF MICROSHUTTER ARRAYS

(71) Applicant: U.S.A. as represented by the Administrator of the National Aeronautics and Space Administration, Washington, DC (US)

(72) Inventors: MARY J. LI, Bethesda, MD (US); YITING WEN, Essex, MD (US); LIQIN WANG, Essex, MD (US); SAMUEL H. MOSELEY, University Park, MD (US); ALEXANDER KUTYREV, Columbia, MD (US)

(21) Appl. No.: 14/855,923

(22) Filed: Sep. 16, 2015

(51) Int. Cl. G02B 26/04; B81C 1/00; B81B 3/00

(52) U.S. Cl. CPC G02B 26/04; B81B 3/0005; B81C 1/00968; B81B 2201/045; B81C 2201/112

(57) ABSTRACT

Methods for actuating a microshutter array with electromechanical resonance and electrostatic force are described herein. An alternating electrical field is created by applying an alternating current (AC) voltage across a pair of actuation electrodes. A shutter blade with a blade electrode thereon is disposed between the pair of actuation electrodes and vibrates in the alternating electrical field created. Direct current (DC) voltages are applied to a vertical electrode and the blade electrode. The shutter blade is attracted to the vertical electrode and captured to an open position.

### JOINT WORK BY GOVERNMENT AND LARGE BUSINESS CONTRACTOR EMPLOYEES

The embodiments described herein was made in the performance of work under a NASA contract and by an employee of the United States Government and is subject to the provisions of Section 305 of the National Aeronautics and Space Act of 1958, Public Law 85-568 (72 Stat. 435; 42 U.S.C. 2457), and may be manufactured and used by or for the Government for governmental purposes without the payment of any royalties thereon or after.

### BACKGROUND

The following description is provided to assist the understanding of the reader. None of the information provided or references cited is admitted to be prior art.

A microshutter device is a key component being used on the Near Infrared Spectrograph (NIRSpec) instrument on the James Webb Space Telescope (JWST), the Next Generation Space Telescope (NGST). NIRSpec is an instrument that allows simultaneous observation of a large number of objects in space. Microshutter arrays are placed in the telescope optical path at the focal plane of NIRSpec detectors for selective transmission of light. A microshutter array comprises a plurality of individually controllable microshutter cells. Each microshutter cell can be placed in either an open state or a closed state. An open microshutter cell lets light in from desired objects, while a closed cell blocks light from objects not desired. Given an image of an area on the sky, the microshutter array can be programmed to admit light from an ensemble of selected objects, providing a capability of simultaneous observation of a large number of objects. Microshutter arrays also have a great potential in other optical applications, such as laser filtering, eye protection, mass-spectroscopy, etc.

The mechanism for opening and closing, i.e., actuation of, microshutter cells in the array is important to the performance of the microshutter array. In a mechanism, the microshutter cells are actuated by a magnetic field. Before observation, a linear magnet sweeps across the array to place each cell in the open state. Then selected cells are closed by dropping an electrostatic force holding the cells to the open position. To scale up the microshutter arrays, a simplified actuation mechanism that has faster opening/closing operations is needed.

### SUMMARY

A method of actuating a microshutter array, a method of fabricating the microshutter array, and the microshutter array itself are described herein. In one aspect, a method of actuating a microshutter array is provided. The method includes vibrating a shutter blade of a microshutter cell that is selected to be opened in an alternating electrical field. The method further includes capturing the shutter blade with an electrostatic force. In some embodiments, the alternating electrical field is generated by applying an alternating current (AC) voltage across a pair of actuation electrodes. The shutter blade is disposed between the pair of actuation electrodes. In some embodiments, the electrostatic force is generated by applying direct current (DC) voltages on the shutter blade and a vertical electrode. The vertical electrode is disposed proximate to the open position of the shutter blade.

In another aspect, a microshutter array is provided. The microshutter array comprises a frame of grid and a plurality of microshutter cells each contained in an openings of the frame. Each of the plurality of microshutter cells includes a shutter blade, a torsion bar, a vertical electrode, and a pair of actuation electrodes. The shutter blade includes a blade electrode. The torsion bar connects the shutter blade to the frame. The shutter blade is rotatable around the torsion bar. The vertical electrode is on a wall of the frame, wherein the wall forms an inside wall of the shutter cell on a side next to the torsion bar. The shutter blade is disposed between the pair of actuation electrodes. In some embodiments, each microshutter cell further comprises a light shield that blocks light from leaking through the gap between the shutter blade, the torsion bar, and the frame when the microshutter cell is in the closed state. In some embodiments, each microshutter cell further comprises an anti-stiction coating.

In another aspect, a method of fabricating a microshutter array is provided. The method comprises forming shutter blade and torsion bar patterns on a substrate. The method further comprises forming a frame out of the substrate and releasing the shutter blade from the substrate. The method further comprises forming vertical electrodes on wall of the frame; attaching the frame to a first transparent substrate; and attaching the frame to a second transparent substrate.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 depicts a schematic view of a microshutter array from the front side in accordance with an illustrative embodiment.

FIG. 2 depicts a perspective view of a microshutter cell in accordance with an illustrative embodiment.

FIG. 3 depicts a perspective view and an exploded view of a strip-shaped blade electrode in accordance with an illustrative embodiment.

FIG. 4 depicts a top view of a serpentine-shaped torsion bar in accordance with an illustrative embodiment.

FIG. 5(A) depicts a cross-sectional view of two microshutter cells in a closed state in accordance with an illustrative embodiment.

FIG. 5(B) depicts a cross-sectional view of two microshutter cells in a transitional resonance state in accordance with an illustrative embodiment.

FIG. 5(C) depicts a cross-sectional view of two microshutter cells in a closed state in accordance with an illustrative embodiment.

FIG. 6 is a flow diagram illustrating fabrication process of a microshutter array in accordance with an illustrative embodiment.

FIG. 7 depicts a schematic view of layers of a shutter blade of a microshutter cell in accordance with an illustrative embodiment.

### DETAILED DESCRIPTION

In the following detailed description, reference is made to the accompanying drawings, which from a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

The present disclosure relates generally to microshutter arrays and more particularly to microshutter arrays actuated by electromechanical resonance and electrostatic force. An alternating electrical field is created by applying an alternating current (AC) voltage across a pair of actuation electrodes. A shutter blade with a blade electrode thereon is disposed between the pair of actuation electrodes and vibrates in the alternating electrical field created. Direct current (DC) voltages are applied to a vertical electrode and the blade electrode. The shutter blade is attracted to the vertical electrode and captured to an open position. Since no magnets are needed in this actuation mechanism, much larger arrays can be achieved. For example, a field of view at least 50 times larger than that of magnetically actuated arrays can be achieved. With the magnets eliminated, the microshutter arrays can be made lighter and less prone to mechanical failure. Advantageously, faster opening/closing operations of shutter cells are enabled. In addition, a standard micromachining technology can be used to simplify the fabrication process.

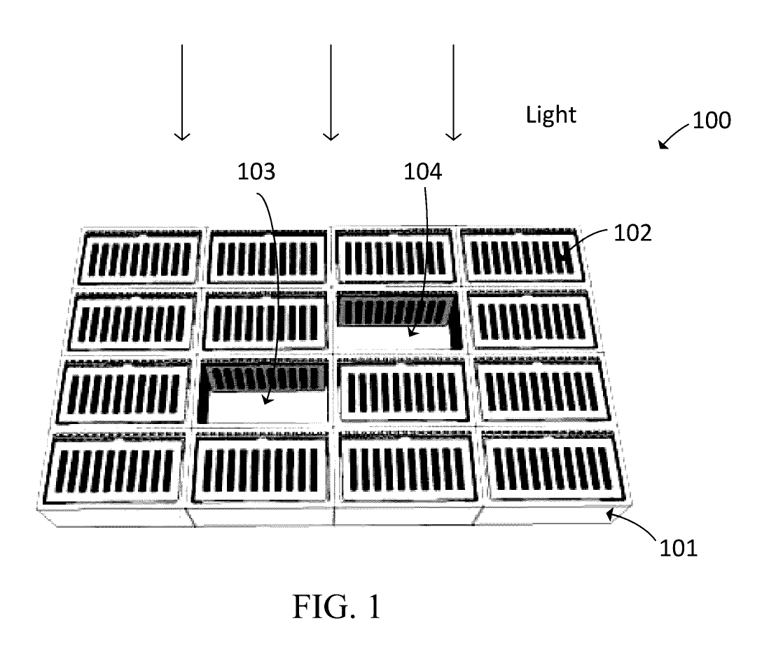

Now refer to FIG. 1. FIG. 1 depicts a schematic view of a microshutter array 100 from the front side in accordance with an illustrative embodiment. Microshutter array 100 comprises a plurality of individually controllable microshutter cells, 102, 103, and 104 for example, each contained in an opening of a frame 101. Frame 101 is a grid of bars that provide structural support for the shutter cells. Although a 4×4 array is illustrated in FIG. 1, a microshutter array may comprise many more cells. For example, a microshutter array may contain 32×32, 128×128, 512×512, or 2048×2048 cells. Each cell can be placed individually in either an open state or a closed state. Microshutter cell 102, for example, is placed in the closed state, blocking light from transmitting through. Microshutter cells 103 and 104 are placed in the open state, letting light in. In an embodiment, each microshutter cell measures 100 by 200 microns (μm). In another embodiment, each microshutter cell measures 100 by 100 microns. It shall be appreciated that the number and dimensions of the microshutter cells given here are for illustration only, not for limiting. The microshutter array may contain any suitable number of cells of any suitable dimensions. In some embodiments, frame 101 is made of single crystal silicon with a thickness of about 100 microns, with a frame width of about 8 microns between the shutter cells. In other embodiments, frame 101 may be made of other appropriate materials with other appropriate configurations.

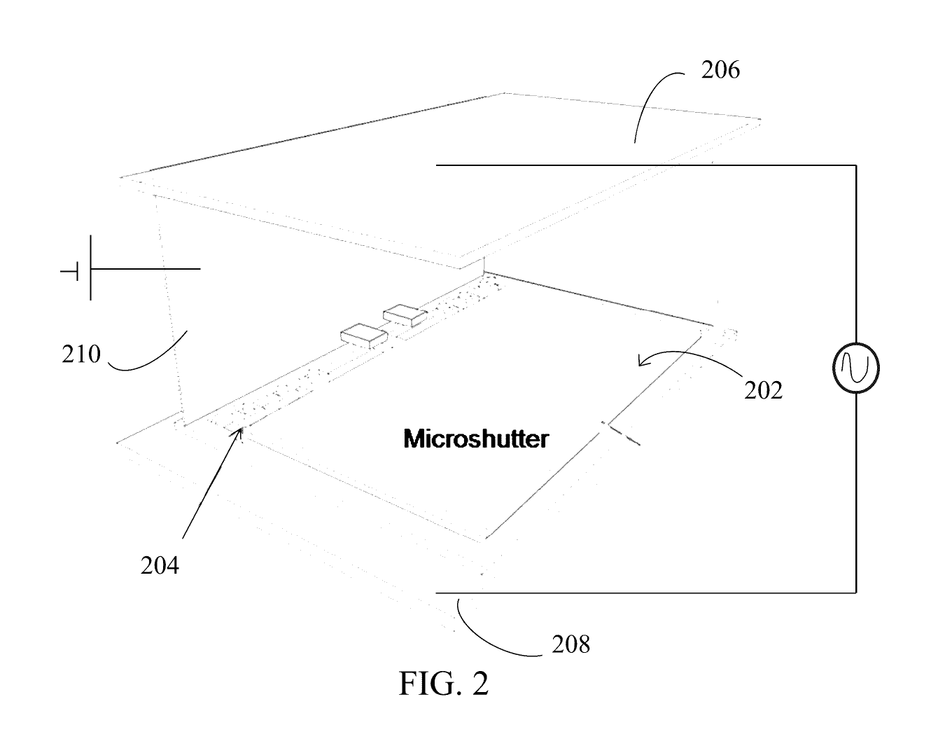

FIG. 2 depicts a perspective view of a microshutter cell 200 in accordance with an illustrative embodiment. Microshutter cell 200 comprises a shutter blade 202, a torsion bar 204, a first actuation electrode 206, a second actuation electrode 208, and a vertical electrode 210. Vertical electrode 210 is formed on a vertical wall of the frame. That vertical wall forms an inside wall of microshutter cell 200 on the side next to torsion bar 204. Vertical electrode 210 comprises a thin conductive layer formed on at least a portion of the inner side of the vertical wall. In some embodiments, the thin conductive thin layer is a metal layer. In some embodiments, the metal layer is an aluminum (Al) layer with a thickness of a few hundred nanometers (nm). In some embodiments, the Al layer is configured to block light and to compensate thermal stress of shutter blade 202. In some embodiments, the metal layer is a titanium/gold (Ti/Au) bilayer with a thickness of a few hundred nanometers. It shall be appreciated that the materials and the dimensions of vertical electrode 210 given here are for illustration only, not for limiting. Vertical electrode may be made of any suitable conductive material with any suitable dimension. In some embodiments, a dielectric layer (not illustrated in the present figure) is formed between vertical electrode 210 and the inner side of the vertical wall. In an embodiment, the dielectric layer is aluminum oxide with a thickness of a few hundred nanometers. In another embodiment, the dielectric layer is silicon dioxide with a thickness of a few hundred nanometers. It shall be appreciated that the dielectric layer may be made of any suitable material with any suitable dimension.

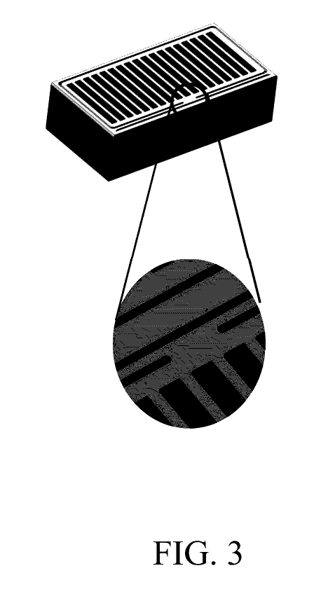

Shutter blade 202 is connected to the vertical wall of the frame through a hinge and torsion bar 204. Shutter blade 202 is a cantilever suspended from the vertical wall. In the illustrated embodiment, shutter blade 202, when actuated, can rotate up to about 90 degree around torsion bar 204. Shutter blade 202 has a blade electrode thereon. In some embodiments, shutter blade 202 includes a dielectric layer and a conductive layer. The conductive layer is used as the blade electrode and the dielectric layer supports the electrode. In some embodiments, the dielectric layer is made of silicon nitride with a thickness of a few hundred microns. In an embodiment, the silicon nitride layer has a thickness of about 250 microns. In another embodiment, the silicon nitride layer has a thickness of about 500 microns. In some embodiments, the blade electrode is made of a thin metal layer, for example, an aluminum (Al) layer with a thickness of a few hundred nanometers (nm) that provides optical opacity. In an embodiment, the Al layer is 200 nm thick. In another embodiment, the Al layer is 800 nm thick The blade electrode may be of various shapes. FIG. 3 depicts a perspective view and an exploded view of a strip-shaped blade electrode in accordance with an illustrative embodiment. In some embodiments, the blade electrode is in the shape of a rectangle. It shall be appreciated that the materials and dimensions of shutter blade 202 given here are for illustration only, not for limiting. Shutter blade 202 may be made of any suitable materials with any suitable dimension. It shall also be appreciated that the shapes of the blade electrode given here are for illustration only, not for limiting. The blade electrode can be of any appropriate shapes.

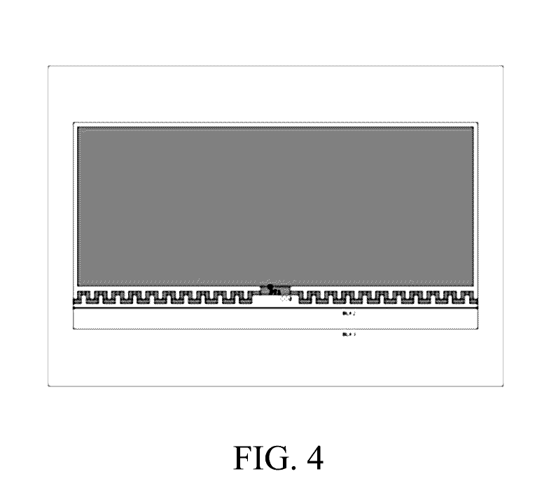

Torsion bar 204 connects shutter blade 202 to the vertical wall of the frame through a hinge. When there is no external force applied on shutter blade 202, it remains in the horizontal closed position. Shutter blade 202 can rotate around torsion bar 204 up to about 90 degree when external force is applied. The rotation of shutter blade 202 produces a twisting action in torsion bar 202 and causes a torque energy to be stored in torsion bar 202 because the ends of the torsion bar are fixed. As a result, when the external force is removed from shutter blade 202, the torque energy stored in torsion bar 204 causes shutter blade 202 to rotate back to the horizontal closed position. In some embodiments, torsion bar 204 is patterned together with shutter blade 202 and therefore has the same layer structures as shutter blade 202. Torsion bar 204 may be of various shapes. FIG. 4 depicts a top view of a serpentine-shaped torsion bar in accordance with an illustrative embodiment. It shall be appreciated that torsion bar 204 can be of any appropriate shapes to achieve a balance between external force needed to open shutter blade 202 and restoring force when shutter blade 202 is to be closed.

Shutter blade 202 is disposed between a pair of actuation electrodes, i.e., first actuation electrode 206 and second actuation electrode 208. First actuation electrode 206 and second actuation electrode 208 are made of optically transparent and electrically conductive materials. In some embodiments, first actuation electrode 206 is made of an indium tin oxide (ITO) film patterned on a first glass substrate; second actuation electrode 208 is made of an ITO film patterned on a second glass substrate. It shall be appreciated that the actuation electrodes and the substrates may be made of any suitable materials.

In some embodiments, a spacer (not illustrated in the present figure) is disposed between shutter blade 202 and second actuation electrode 208 so that shutter blade 202 is not in direct contact with second actuation electrode 208. The spacer has an opening under shutter blade 202. In some embodiments, the space is made of a silicon oxide layer or other insulating material layer patterned on the second transparent substrate.

In some embodiments, an light shield (not illustrated in the present figure) is disposed between shutter blade 202 and second actuation electrode 208. The light shield has an opening under shutter blade 202. In some embodiments, the light shield is made of an optically opaque material patterned on the second transparent substrate. The light shield blocks light from leaking through the gaps between shutter blade 202, torsion bar 204, and the frame when microshutter cell 200 is in the closed state.

In some embodiments, shutter blade 202 is coated with an anti-stiction coating (not illustrated in the present figure). In some embodiments, the anti-stiction coating is a oxide/organic material composite layer, the oxide side attaching to surfaces of shutter blade 202, and the organic material side facing out. In some embodiments, the organic material is an hydrophobic monolayer that prevents shutter blade 202 from sticking to either the light shield or vertical electrode 210.

The configurations shown in FIG. 2 are provided for purposes of illustration only. It should be appreciated that other embodiments may include, fewer, more, or different components than those illustrated in FIG. 2 and such components may be combined in the same or different configurations. All such modifications are contemplated within the scope of the present disclosure.

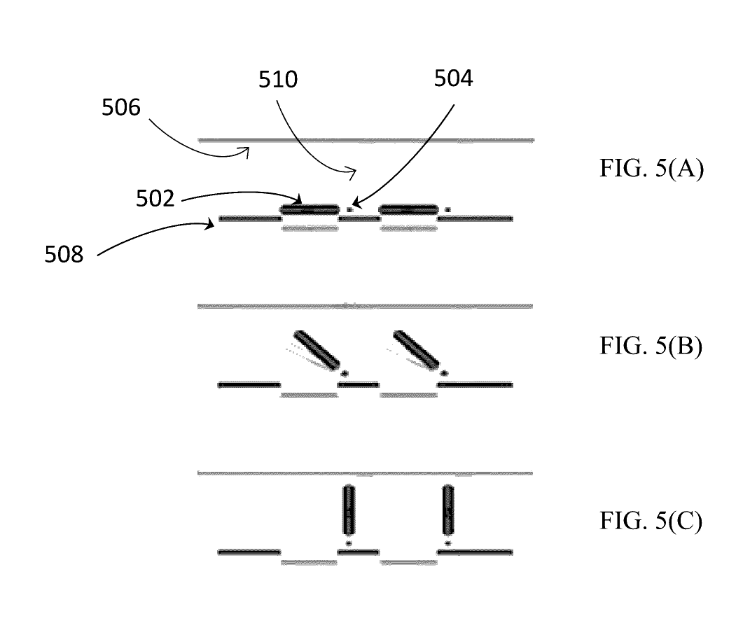

FIGS. 5(A) through 5(C) depict an actuation process of microshutter cells in accordance with an illustrative embodiment. Specifically, FIG. 5(A) depicts a cross-sectional view of two microshutter cells in a closed state. FIG. 5(B) depicts a cross-sectional view of two microshutter cells in a transitional resonance state. FIG. 5(C) depicts a cross-sectional view of two microshutter cells in an open state.

In FIG. 5(A), shutter blade 502 is in the horizontal closed position when no external force or insufficient external force is applied. In FIG. 5(B), an alternating current (AC) voltage is applied across first actuation electrode 506 and second actuation electrode 508. Accordingly, an alternating electrical field is created in the space between first actuation electrode 506 and second actuation electrode 508. Shutter blade 502, in the alternating electrical field, deflects from the horizontal closed position and vibrates. When the frequency of the alternating electrical field matches the frequency of the mechanical resonance of shutter blade 502, the deflection and the vibration of shutter blade 502 peaks. In FIG. 5(C), direct current (DC) voltages are applied to blade electrode on shutter blade 502 and vertical electrode 510. For example, a positive voltage is applied to the blade electrode, and a negative voltage applied to vertical electrode 510. Alternatively, a negative voltage is applied to the blade electrode, and a positive voltage applied to vertical electrode 510. The shutter blade is attracted to vertical electrode 510 by electrostatic force and captured by vertical electrode 510 to the vertical open position.

The rotation of shutter blade 502 produces a twisting action in torsion bar 504 and causes a torque energy to be stored in torsion bar 504 because the ends of the torsion bar are fixed. When the DC voltages are dropped or removed from vertical electrode 510 and the blade electrode, the torque energy stored in torsion bar 504 causes shutter blade 502 to rotate back to the horizontal closed position. In other words, if the electrodes are biased to provide enough electrostatic force to overcome the mechanical restoring force of torsion bar 504, shutter blade 502 remains attached to vertical electrode 510 in its open state. If the bias is insufficient, shutter blade 502 returns to its horizontal closed position.

In some embodiments, the level of the actuation AC voltage applied across first actuation electrode 506 and second actuation electrode 508 is in the range of about 5 Vac to about 35 Vac. In some embodiments, the frequency of the actuation AC voltage is in the range of about 1 KHz to about 4 KHz, depending on the mechanical resonance frequency of shutter blade 502. The level of the capture DC voltages applied on the blade electrode and vertical electrode 510 is in the range of about 20 Vdc to about 40 Vdc.

As noted above, when the frequency of the alternating electrical field matches the frequency of the mechanical resonance of shutter blade 502, the deflection and the vibration of shutter blade 502 peaks. Various methods can be used for obtaining the mechanical resonance frequency of shutter blade 502. In some embodiments, a finite element analysis method is employed to determine the resonance frequency by using micro-electro-mechanical system (MEMS) module structural mechanics-eigenmode analysis. In other embodiments, microshutter actuation is directly observed inside a scanning electron microscope (SEM) when an AC voltage is applied to vibrate the shutter. If the AC frequency is equivalent to one-half of the mechanical resonance frequency of the shutter blade, a maximum deflection of the shutter should be observed. In yet other embodiments, a voltage drop across a resistor placed in series with the microshutter is measured to determine the mechanical resonance frequency of the microshutter. In this method, the microshutter is treated as a capacitor. When it is vibrating its capacitance oscillates at a rate equal to its resonance frequency. By measuring the voltage drop across a resistor placed in series with the microshutter with an oscilloscope, the resonance frequency of the microshutter is obtained.

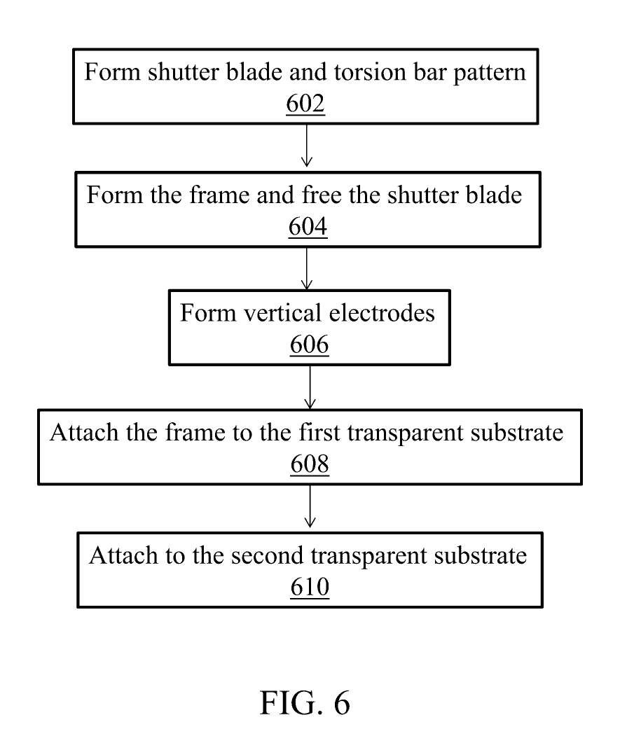

FIG. 6 is a flow chart illustrating fabrication process of a microshutter array in accordance with an illustrative embodiment. In alternative embodiments, fewer, additional, and/or different operations may be performed. Also, the use of a flow diagram is not meant to be limiting with respect to the order of operations performed.

Microshutter array fabrication is carried out through semiconductor processing and micro-electromechanical (MEMS) techniques. Photolithography, wet chemical etching, dry reactive ion etching, electron-beam, and sputtering deposition, etc. are employed to fabricate the microshutter arrays.

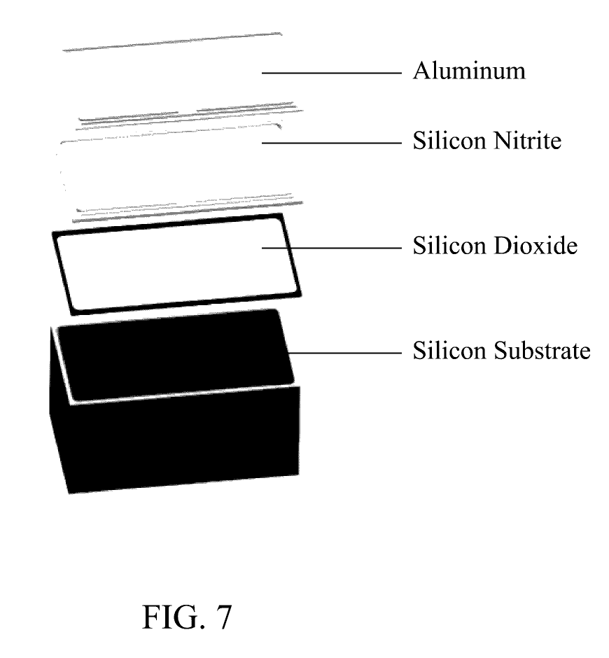

In an operation 602, shutter blade and torsion bar patterns are formed. In some embodiments, a silicon wafer with a thickness of a few hundred microns is used as the frame material to provide structural support for shutter cells. In other embodiments, the frame is made out of a silicon on oxide (SOI) wafer. In yet other embodiment, the frame may be made out of other materials. As shown in FIG. 7, a layer of silicon dioxide is formed over the silicon substrate as an etch stop layer. The silicon dioxide layer may be formed by low-temperature growth, thermal growth, or other appropriate methods. In an embodiment, the silicon dioxide layer is 250 microns thick. A layer of silicon nitride is then formed over the silicon dioxide layer. In some embodiments, the silicon nitride layer is formed by low pressure chemical vapor deposition (LPCVD). In an embodiment, the silicon nitride layer is 250 microns thick. In another embodiment, the silicon nitride layer is 500 microns thick. A thin layer of aluminum (Al) is formed over the silicon nitride layer. In some embodiments, the Al layer is formed by sputter deposition. In an embodiment, the Al layer is 200 nanometer (nm) thick. In another embodiment, the Al layer is 800 nm thick. The Al layer is used as the blade electrode and provides optical opacity. It shall be appreciated that the materials, growth methods, and dimensions of each layer are given for illustration only, not for limiting. Any appropriated materials, growth methods, and dimensions may be used.

There are a number of ways for forming the shutter blade and torsion bar patterns. In some embodiments, the pattern of the blade electrode is formed by wet etching the Al layer. In an embodiment, the electrode pattern are in the shape of strips, as shown in FIG. 3, for example. The silicon nitride layer is then etched into the shutter blade and torsion bar geometries. In some embodiments, the silicon nitride layer is etched by a reactive ion etching (RIE). Depending on the mask set used in etching processes, a single wafer may yield six 128×128 microshutter arrays, ten 32×32 arrays, a number of 8×8 arrays, or any other appropriate numbers. The mask set incorporates the shutter blade design with variations of torsion bar widths and shutter frame widths. In an embodiment, each microshutter cell is 100 microns by 200 microns in dimension. In another embodiment, each cell is 100 microns by 100 microns. It shall be appreciated that the methods of patterning and the dimensions of the cells are given here for illustration only, not for limiting. Any suitable method may be employed to made cells of any suitable dimensions. In this manner, shutter blade and torsion bar patterns are formed on the substrate.

In an operation 604, the frame that provides structural support for the microshutter cells is formed and the shutter blades are released from the substrate. The portion of the silicon wafer and the silicon oxide layer under the patterned silicon nitride layer is removed to free the shutter blades. The remaining portion of the wafer forms the frame. In some embodiments, the wafer is etched by anisotropic thinning followed by a deep reactive ion etching (DRIE). In an embodiment, the wafer is etched to 100 microns thick. In some embodiment, the wafer is flipped over and attached to another transparent wafer for easy handling during the thinning and subsequent processing. In some embodiments, the silicon dioxide layer is etched off by using a buffered hydrofluoric acid (BHF) etching. In some embodiments, a mask set is used for the etching processes. It shall be appreciated that the methods of patterning the wafer and the silicon dioxide layer are given for illustration only, not for limiting. Any suitable method may be employed. In this manner, the frame is formed, the shutter blades are released from the substrate and suspended from the frame via the torsion bars.

In an operation 606, the vertical electrodes are formed. The vertical electrode is formed on the vertical wall of the frame which forms an inside wall of the shutter cell on the side next to the torsion bar. A thin conductive layer is formed on at least a portion of the vertical wall. In some embodiments, the thin conductive layer is an Al film. In an embodiment, the Al film is formed by an angle deposition. In another embodiment, the Al film is formed by an atomic layer deposition (ALD). In yet another embodiment, the Al film is formed by an electron beam (E-beam) deposition. The metal thin layer may be several hundred nm thick. In an embodiment, the metal layer is 200 nm thick. It shall be appreciated that the material, growth method, and the dimension of the vertical electrodes are given here for illustration only, not for limiting. Any suitable material, growth method, and dimension may be employed. In some embodiments, a dielectric layer is formed between the vertical wall of the frame and the thin metal layer. In an embodiment, the dielectric layer is aluminum oxide formed by vapor deposition. Dielectric layer made of other suitable materials by other methods can be employed. In this manner, vertical electrodes are made on the vertical walls of the frame.

In an operation 608, the frame with the microshutter cells is attached to a first optically transparent substrate. The first actuation electrodes are patterned on the first transparent substrate. In some embodiments, the first transparent substrate is a glass substrate. In some embodiments, the first actuation electrodes are made of an ITO film patterned on the first transparent substrate by photolithography. It shall be appreciated that other suitable materials can be used as the first transparent substrate and the first actuation electrode. In some embodiments, alignment features are patterned on both the frame and the first transparent substrate for aligning the first actuation electrodes with the microshutter cells. In this manner, the frame and the first transparent substrate are aligned and bonded together.

In an operation 610, the frame is attached to a second transparent substrate. The second actuation electrodes are patterned on the second transparent substrate. In some embodiments, the second transparent substrate is a glass substrate. In some embodiments, the second actuation electrodes are made of an ITO film patterned on the second transparent substrate by photolithography. In some embodiments, spacers are also patterned on the second transparent substrate so that the shutter blades are not in direct contact with the second actuation electrodes. In some embodiments, the spacers are made of a silicon dioxide layer or other insulating material layer patterned on the second substrate by photolithography. In some embodiments, light shields are patterned on the second transparent substrate for blocking light from leaking through the gaps between the shutter blades, the torsion bars, and the frame when microshutter cells are in the closed state. In some embodiments, the light shields are made of an Al layer patterned on the second transparent substrate by photolithography. In some embodiments, alignment features are patterned on both wafers for aligning the second transparent electrodes with the first transparent electrodes. Photolithography can be used to make the alignment features. In this manner, the frame and the second transparent substrate are aligned and bonded together.

As utilized herein, the terms “approximately,” “about,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

References herein to the positions of elements (e.g., “on,” “under,” “above,” “below,” “horizontal,” “vertical,” etc.) are merely used to describe the orientation of various elements in the FIGURES. It should be noted that the orientation of various elements may differ according to other exemplary embodiments, and that such variations are intended to be encompassed by the present disclosure.

While various embodiments of the methods and systems have been described, these embodiments are exemplary and in no way limit the scope of the described methods or systems. Those having skill in the relevant art can effect changes to form and details of the described methods and systems without departing from the broadest scope of the described methods and systems. Thus, the scope of the methods and systems described herein should not be limited by any of the exemplary embodiments and should be defined in accordance with the accompanying claims and their equivalents.

What is claimed is:

1. A method of actuating a microshutter array, the method comprising:
vibrating a shutter blade of a microshutter cell that is selected to be opened in an alternating electrical field; and
capturing the shutter blade to an open position with an electrostatic force.

2. The method of claim 1, further comprising:
generating the alternating electrical field by applying an alternating current (AC) voltage across a pair of actuation electrodes, wherein the shutter blade is disposed between the pair of actuation electrodes.

3. The method of claim 2, wherein a level of the AC voltage applied across the pair of actuation electrodes is in a range of about 5 Vac to about 35 Vac.

4. The method of claim 2, wherein a frequency of the AC voltage applied across the pair of actuation electrodes matches a mechanical resonance frequency of the shutter blade.

5. The method of claim 2, wherein a frequency of the AC voltage applied across the pair of actuation electrodes is in a range of about 1 KHz to about 4 KHz.

6. The method of claim 1, further comprising:
generating the electrostatic force by applying direct current (DC) voltages on the shutter blade and a vertical electrode, wherein the vertical electrode is disposed proximate to the open position of the shutter blade.

7. The method of claim 2, wherein the DC voltages applied on the shutter blade and the vertical electrode are opposite DC voltages, and wherein a level of the DC voltages is in a range of about 20 Vdc to about 40 Vdc.

8. A microshutter array, comprising:
a frame of grid; and
a plurality of microshutter cells each contained in an opening of the frame, wherein each of the plurality of microshutter cells includes:
a shutter blade including a blade electrode;
a torsion bar connecting the shutter blade to the frame, wherein the shutter blade is rotatable around the torsion bar;
a vertical electrode on a vertical wall of the frame, wherein the vertical wall forms an inside wall of the microshutter cell on a side next to the torsion bar;
a first actuation electrode; and
a second actuation electrode, wherein the shutter blade is disposed between the first actuation electrode and the second actuation electrode.

9. The microshutter array of claim 8, wherein the frame is made of silicon.

10. The microshutter array of claim 8, wherein the shutter blade comprises a silicon nitride layer and an aluminum (Al) layer, where the blade electrode comprise the Al layer.

11. The microshutter array of claim 9, wherein the Al layer is in a strip-shaped pattern.

12. The microshutter array of claim 8, wherein the torsion bar is in a serpentine-shaped pattern.

13. The microshutter array of claim 8, wherein the first actuation electrode comprises a first indium tin oxide (ITO) layer patterned on a first transparent substrate, and wherein the second actuation electrode comprises a second indium tin oxide (ITO) layer patterned on a second transparent substrate.

14. The microshutter array of claim 8, wherein the shutter blade is configured to switch between an closed state and an open state, wherein the shutter blade covers the opening of the frame in the closed state, and wherein the shutter blade does not cover the opening of the frame in the closed state.

15. The microshutter array of claim 8, further comprising a light shield that blocks light from leaking through the gaps between the shutter blade, the torsion bar, and the frame when the microshutter cell is in the closed state.

16. The microshutter array of claim 8, wherein the shutter blade is coated with an anti-stiction coating.

17. A method of fabricating a microshutter array, the method comprising:
forming shutter blade and torsion bar patterns on a substrate;
forming a frame out of the substrate and releasing the shutter blade from the substrate, wherein the frame is a grid with a plurality of openings;
forming vertical electrodes on walls of the frame;
attaching the frame to a first transparent substrate; and
attaching the frame to a second transparent substrate.

18. The method of claim 16, wherein the forming shutter blade and torsion bar patterns on a substrate further comprising:
forming a silicon dioxide layer above the substrate;
forming a silicon nitride layer above the silicon dioxide layer;
forming an aluminum layer above the silicon nitride layer; and
etching the silicon nitride layer and the aluminum layer to the shutter blade and torsion bar patterns.

19. The method of claim 16, further comprising forming a light shield.

20. The method of claim 16, further comprising forming an anti-stiction coating.
